(19) United States
(12) Patent Application Publication
(10) Pub. No.: US 2012/0118615 A1
(43) Pub. Date: May 17, 2012

(54) METAL CLAD LAMINATE, METHOD OF MANUFACTURING THE SAME, AND HEAT-RADIATING SUBSTRATE

(75) Inventors: Kwan Ho LEE, Seoul (KR); Seog Moon CHOI, Seoul (KR); Tae Hyun KIM, Seoul (KR)

(73) Assignee: SAMSUNG ELECTRO-MECHANICS CO., LTD., Gyunggi-do (KR)

(21) Appl. No.: 13/091,016

(22) Filed: Apr. 20, 2011

(30) Foreign Application Priority Data
Nov. 11, 2010 (KR) 10-2010-0112282

(51) Int. Cl. H05K 1/03; B32B 37/24; B32B 15/04; B32B 7/02; B82Y 40/00; B82Y 30/00

(52) U.S. Cl. 174/252; 428/457; 428/213; 156/307.5; 977/742; 977/734; 977/847; 977/932

(57) ABSTRACT

Disclosed herein is a metal clad laminate, a method of manufacturing the same and a heat-radiating substrate using the same. The metal clad laminate has increased adhesion because a layer of carbon nanoparticles is formed between bonding surfaces of upper and lower metal foils to a prepreg, and has improved heat conductive properties and mechanical properties because the prepreg has carbon fibers incorporated therein. Also, resin members having carbon nanofibers incorporated therein may be alternately stacked with metal layers, and metal layers may be inserted in the prepreg thus improving heat conductive properties, and the number of stacked layers may vary depending on the end use thereby controlling heat conductive properties and mechanical properties of the metal clad laminate.

### CROSS REFERENCE TO RELATED APPLICATION

This application claims the benefit of Korean Patent Application No. 10-2010-0112282, filed Nov. 11, 2010, entitled “Metal clad laminate and method for manufacturing the same, heat-radiating substrate”, which is hereby incorporated by reference in its entirety into this application.

### BACKGROUND OF THE INVENTION

1. Technical Field

The present invention relates to a metal clad laminate, a method of manufacturing the same, and a heat-radiating substrate using the same.

2. Description of the Related Art

Power devices and power modules recently being applied in a variety of fields have heat-radiating problems, and in order to solve such problems, attempts are being made to manufacture various heat-radiating substrates using metal materials having high heat conductive properties. Particularly, the recent trend of reducing the size and thickness of electronic components is increasing the density of devices generating heat that are received on a local area of a heat-radiating substrate, thus increasing the demand for dissipating heat emitted from the device generating heat to outside the substrate quickly.

A metal clad laminate is widely utilized as a base substrate of a heat-radiating substrate because of superior stamping processability and drilling processability and because it is inexpensive. In the case of a metal clad laminate for use in a heat-radiating substrate, heat conductive properties are regarded as more important than all other considerations.

Such a metal clad laminate includes an insulating layer and metal foils formed on upper and lower surfaces of the insulating layer. In the case of the upper metal foil, a circuit pattern is formed and electronic components such as semiconductor chips are mounted. Whereas, the lower metal foil is exposed to the outside and is thus used to dissipate heat. Conventionally useful is a double-sided copper clad laminate which is configured such that copper foils are pressed at high temperature and bonded to upper and lower surfaces of an insulating layer made of ceramic.

However, the double-sided copper clad laminate is disadvantageous because ceramic used for the insulating layer has low heat conductivity in terms of transferring heat to the outside because of the high performance and high density of the devices generating heat. In order to improve a heat-radiating function, the size of the heat-radiating substrate should be increased and a heat-radiating device should be externally mounted, and thus the extent to which the heat-radiating function of the double-sided copper clad laminate can be increased is limited.

Furthermore, because ceramic is brittle, its applications are confined. In the case of the conventional double-sided copper clad laminate, it is difficult to control heat-radiating properties and mechanical properties such as strength depending on the end use.

### SUMMARY OF THE INVENTION

Accordingly, the present invention has been made keeping in mind the problems encountered in the related art and the present invention is intended to provide a metal clad laminate which includes a prepreg having carbon fibers incorporated therein, a layer of carbon nanoparticles formed on upper and lower surfaces of the prepreg, and a metal foil bonded thereto, so that the heat-radiating function and mechanical properties of the metal clad laminate may be improved thanks to high heat conductivity and strength of carbon fibers.

An aspect of the present invention provides a metal clad laminate, comprising a prepreg including a resin member and carbon fibers unidirectionally arranged and incorporated therein, an upper layer of carbon nanoparticles formed on an upper surface of the prepreg, and an upper metal foil formed on an upper surface of the upper layer of carbon nanoparticles.

In this aspect, the metal clad laminate may further comprise a lower layer of carbon nanoparticles formed on a lower surface of the prepreg, and a lower metal foil formed on a lower surface of the lower layer of carbon nanoparticles.

In this aspect, the prepreg may include a plurality of metal layers inserted therein.

In this aspect, the lower metal foil may be thicker than the upper metal foil.

In this aspect, the upper metal foil, the lower metal foil and the metal layer may be made of an identical metal.

In this aspect, the resin member may comprise a heat curable resin.

In this aspect, the carbon nanoparticles may be any one selected from among carbon nanotubes (CNTs), Graphene, and carbon black.

Another aspect of the present invention provides a heat-radiating substrate, comprising a metal clad laminate comprising a prepreg including a resin member and carbon fibers unidirectionally arranged and incorporated therein, an upper layer of carbon nanoparticles on an upper surface of the prepreg, a lower layer of carbon nanoparticles formed on a lower surface of the prepreg, a circuit layer on an upper surface of the upper layer of carbon nanoparticles, and a lower metal foil formed on a lower surface of the lower layer of carbon nanoparticles, and an electronic device electrically connected to the circuit layer.

In this aspect, the prepreg may include a plurality of metal layers inserted therein.

In this aspect, the lower metal foil may be thicker than the circuit layer.

A further aspect of the present invention provides a method of manufacturing a metal clad laminate, comprising (A) forming a prepreg including a resin member having carbon fibers incorporated therein, (B) applying a solution of carbon nanoparticles on a bonding surface of a metal foil to the prepreg, thus forming a layer of carbon nanoparticles, (C) drying the metal foil, and (D) bonding the metal foil so that the layer of carbon nanoparticles faces one or both surfaces of the prepreg.

In this aspect, forming the prepreg in (A) may be carried out by alternately stacking a plurality of resin members having carbon fibers incorporated therein with a plurality of metal layers thus forming a prepreg.

In this aspect, forming the prepreg in (A) may be carried out by applying a resin solution on the carbon fibers and then performing drying and rolling thus forming the resin member having the carbon fibers incorporated therein.

In this aspect, the solution of carbon nanoparticles may be prepared by mixing carbon nanoparticles with a volatile solvent.

In this aspect, bonding the metal foil in (D) may be carried out using a press.

### BRIEF DESCRIPTION OF THE DRAWINGS

The features and advantages of the present invention will be more clearly understood from the following detailed description taken in conjunction with the accompanying drawings, in which:

FIGS. 1 to 5 are cross-sectional views showing a metal clad laminate according to an embodiment of the present invention; and

FIG. 6 is a cross-sectional view showing a heat-radiating substrate according to an embodiment of the present invention; and

FIGS. 7 to 11 are views sequentially showing a process of manufacturing the metal clad laminate according to the embodiment of the present invention.

### DESCRIPTION OF SPECIFIC EMBODIMENTS

Hereinafter, embodiments of the present invention will be described in detail while referring to the accompanying drawings. The same reference numerals are used throughout the drawings to refer to the same or similar elements. Moreover, descriptions of known techniques, even if pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

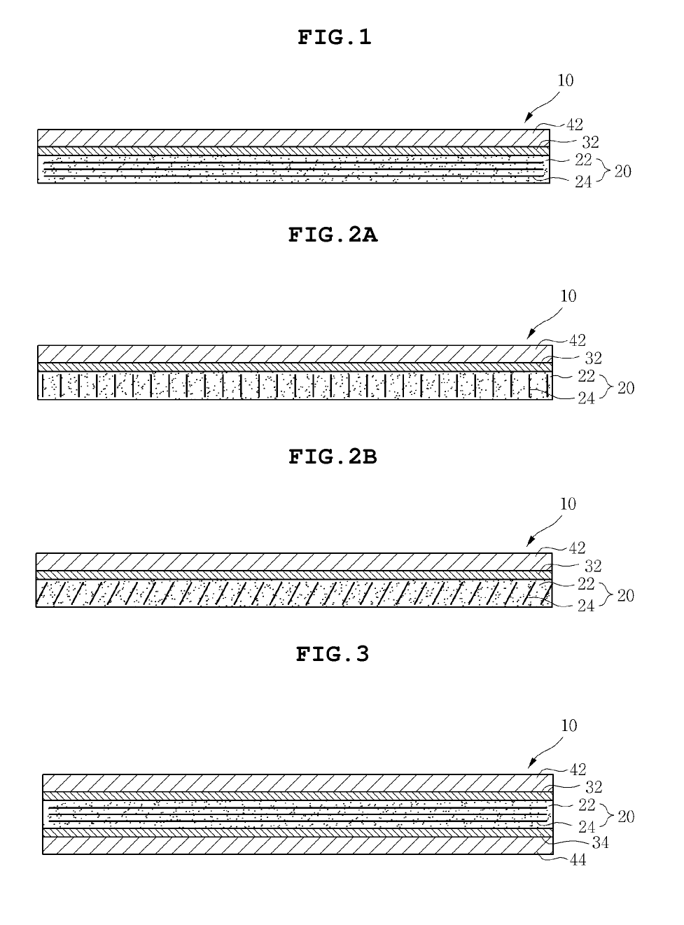

FIG. 1 is a cross-sectional view of a metal clad laminate 10 according to an embodiment of the present invention. The metal clad laminate 10 includes a prepreg 20 including a resin member 22 and carbon fibers 24 unidirectionally arranged and incorporated therein, an upper layer 32 of carbon nanoparticles formed on the upper surface of the prepreg 20, and an upper metal foil 42 adhered to the upper layer 32 of carbon nanoparticles. The metal clad laminate 10 according to the present invention has heat conductive properties and mechanical properties such as strength superior to those of conventional cases, because it includes the prepreg 20 having the carbon fibers 24 incorporated therein. With reference to the drawings, the elements of the metal clad laminate 10 are described below.

The prepreg 20 is configured such that carbon fibers 24 are incorporated in the resin member 22 that is semi-cured. The resin member 22 may include an insulating material such as a curable resin such as a UV curable resin, a heat curable resin or the like, a thermoplastic resin or a liquid crystal polymer. The resin member 22 is contained in an amount of 40˜70% of the total weight depending on the standard of the prepreg 20.

The resin member 22 may include a heat curable resin. Because a heat curable resin is cured by heat, it facilitates the adhering of the metal foil 40 upon application of heat and pressure using a press 80 in a subsequent process, and also results in low deformation when being used for a heat-radiating substrate 100 and a low manufacturing cost. Examples of the heat curable resin which has high adhesion to metal may include urea resin, melamine resin, bismaleimide resin, polyurethane resin, benzoxazine ring-containing resin, cyanate ester resin, bisphenol S type epoxy resin, bisphenol F type epoxy resin, and copolymer epoxy resin of bisphenol S and bisphenol F.

The carbon fibers 24 refer to carbon-containing fibers obtained by heating an organic fiber precursor. The carbon fibers are as light as ⅕ of the weight of steel and have a strength 10 times higher than that of steel, and are thus widely used in the aerospace industry, defense industry and so on. Depending on the manufacturing method, polyacrylonitrile-, pitch-, or rayon-based carbon fibers 24 exemplify the fibers. As shown in FIG. 2, the carbon fibers 24 may be arranged in various directions, including a horizontal direction (FIG. 1), a perpendicular direction (FIG. 2A) or a diagonal direction (FIG. 2B), relative to the plane of the resin member 22. Depending on the direction of array of the carbon fibers 24 incorporated in the prepreg 20, heat transfer effects in a specific direction may increase. As the amount of carbon fibers 24 incorporated in the prepreg 20 becomes larger, heat conductive properties become superior, and the strength of the metal clad laminate 10 may increase. In addition, fiber material such as woven or nonwoven fabric of glass fibers or organic fibers may be further incorporated.

The layer 30 of carbon nanoparticles is formed on one or both surfaces of the prepreg 20, and functions to enhance the force of adhesion between the metal foil 40 and the prepreg 20 by means of carbon particles having a small particle size of ones of nm. Such carbon nanoparticles may be carbon nanotubes (CNTs), Graphene, carbon black, etc.

The metal foil 40 is formed on the layer 30 of carbon nanoparticles. The metal foil 40 which is made of metal exhibits high heat transfer effects and high strength and thus results in high resistance to warpage. The metal foil 40 may be formed of copper (Cu), aluminum (Al), nickel (Ni), magnesium (Mg), titanium (Ti), zinc (Zn), tantalum (Ta) or alloys thereof. Particularly useful is a metal foil 40 made of Cu. Cu has a high heat conductivity of 397 W/mK and is easy to process upon formation of a circuit pattern.

As shown in FIG. 3, the metal clad laminate 10 may further include a lower layer 34 of carbon nanoparticles formed on the lower surface thereof and a lower metal foil 44 adhered to the lower layer 34 of carbon nanoparticles. Because the lower metal foil 44 is provided under the metal clad laminate, heat transfer effects to the outside adjacent to the lower metal foil 44 may increase, and resistance of the metal clad laminate 10 to external stress may be balanced, thus reducing deformation of the metal clad laminate 10 when it suffers an impact. The lower metal foil 44 may be made of Cu or Al which have high heat conductivity.

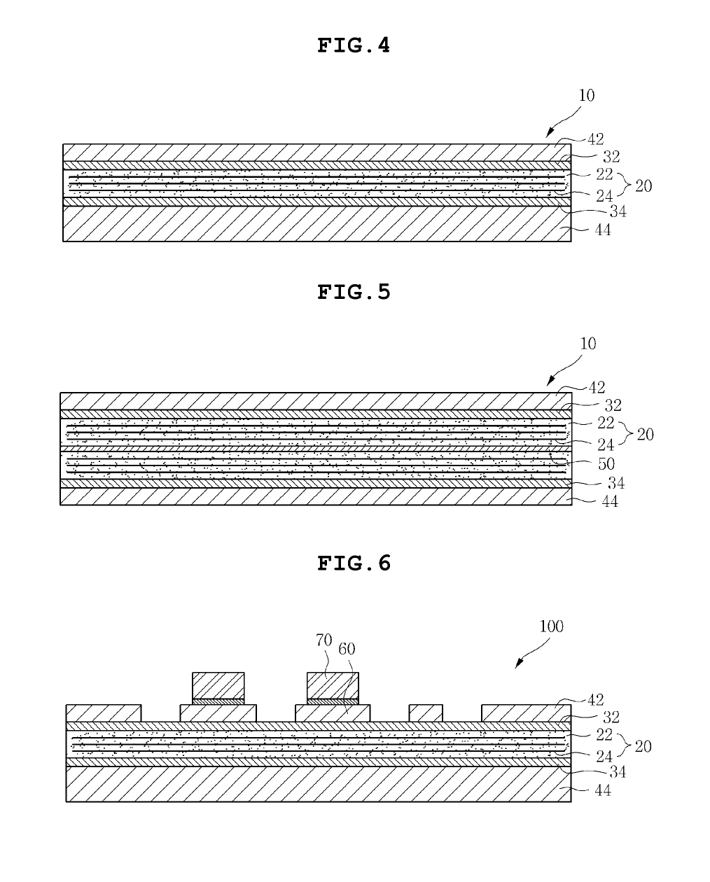

As shown in FIG. 4, the lower metal foil 44 may be thicker than the upper metal foil 42. Because a device generating heat such as an electronic device 70 is mounted on the upper metal foil 42, the lower metal foil 44 is formed to be thicker so that heat generated from the device generating heat is transferred to the upper metal foil 42 and is thus emitted to the outside. Thereby, the lower metal foil 44 which is exposed to the outside may rapidly absorb heat. Also, a heat-radiating device such as a heat sink may be further attached to the lower metal foil 44.

As shown in FIG. 5, the metal clad laminate 10 may be configured such that a plurality of metal layers 50 is inserted in the prepreg 20. Specifically, resin members 22 having the carbon fibers 24 incorporated therein are alternately stacked with the metal layers 50. In the case where the heat value of the electronic device 70 is high, a multilayered structure is formed thus increasing heat conductivity. On the other hand, in the case where the heat value is not high, the number of stacked layers may be decreased and thus the metal clad laminate 10 is made lighter. Furthermore, the metal layer 50 is inserted, so that the metal clad laminate 10 may have increased heat conductivity and strength and also warping properties can vary depending on the type of metal layer 50. The layer 30 of carbon nanoparticles may be formed on the upper and lower surfaces of the metal layer 50 so as to increase adhesion of the metal layer 50 to the prepreg 20.

As such, the upper metal foil 42, the lower metal foil 44 and the metal layer 50 may be made of the same metal. When the upper metal foil 42, the lower metal foil 44 and the metal layer 50 are made of the same metal, a difference in the coefficient of thermal expansion may decrease thus reducing thermal stress upon heating to high temperature. Furthermore, it is easy for them to be handled in the manufacturing process because their warping properties are identical, and there is a low concern about damage resulting from receiving an external impact. The upper metal foil 42, the lower metal foil 44 and the metal layer 50 may be of the same type of metal, such as Cu or Al.

As shown in FIG. 6, a heat-radiating substrate 100 according to the present invention includes a metal clad laminate 10 composed of a prepreg 20 including a resin member 22 and carbon fiber 24 unidirectionally arranged and incorporated therein, an upper layer 32 of carbon nanoparticles formed on the upper surface of the prepreg 20, a lower layer 34 of carbon nanoparticles formed on the lower surface of the prepreg 20, a circuit layer 60 formed on the upper surface of the upper layer 32 of carbon nanoparticles, and a lower metal foil 44 formed on the lower surface of the lower layer 34 of carbon nanoparticles, and an electronic device 70 electrically connected to the upper surface of the circuit layer 60 of the metal clad laminate 10.

The circuit layer 60 is formed by patterning the upper metal foil 42 of the metal clad laminate 10 using etching. As such, the circuit layer 60 may be formed using a semi-additive process, an additive process, a subtractive process. Although a single circuit layer 60 is illustrated in FIG. 6, the present invention is not limited thereto and a build-up layer including an insulating layer, a circuit layer 60, and a via hole may be further formed thereon.

The electronic device 70 includes a connection terminal thereunder so as to be electrically connected to the upper surface of the circuit layer 60, and is thereby mounted on the heat-radiating substrate 100. The electronic device 70 may include a semiconductor device, a passive device, an active device, etc., or a device having high heat value may be used. For example, an insulated gate bipolar transistor (IGBT) or a diode may be used, and an LED package may be provided. Heat generated from the electronic device 70 sequentially passes through the circuit layer 60, the prepreg 20, and the lower metal foil 44, and is thus emitted to the outside.

The metal clad laminate 10 of the heat-radiating substrate 100 may be configured such that resin members 22 having carbon fibers 24 incorporated therein are alternately stacked with metal layers 50 thus forming a prepreg 20, a layer 30 of carbon nanoparticles is formed on upper and lower surfaces thereof, and a metal foil 40 is formed on one or both surfaces thereof.

In the heat-radiating substrate 100, the lower metal foil 44 may be formed to be thicker than the circuit layer 60.

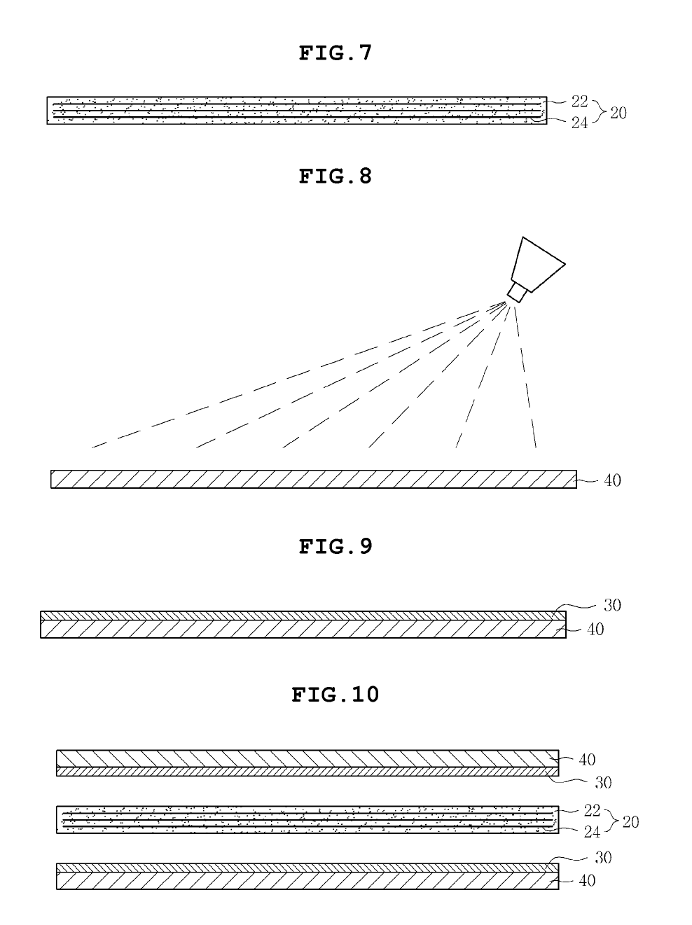

FIGS. 7 to 11 sequentially show the process of manufacturing the metal clad laminate 10 according to the embodiment of the present invention. The method of manufacturing the metal clad laminate 10 according to the present invention includes (A) forming a prepreg 20 including a resin member 22 having carbon fibers 24 incorporated therein, (B) applying a solution of carbon nanoparticles on the bonding surface of a metal foil 40 to the prepreg 20 thus forming a layer 30 of carbon nanoparticles, (C) drying the metal foil 40, and (D) bonding the metal foil 40 so that the layer 30 of carbon nanoparticles faces one or both surfaces of the prepreg 20.

The steps of the process are described hereinafter with reference to the drawings.

As shown in FIG. 7, the prepreg 20 including the resin member 22 having the carbon fibers 24 incorporated therein is formed. The prepreg 20 may be formed by dipping the carbon fibers 24 into a resin solution resulting from dissolving a resin in a solvent or applying the resin solution on the carbon fibers 24 and then performing drying and rolling. The resin solution may include an inorganic filler such as silica, aluminum hydroxide or calcium carbonate, or an organic filler such as crosslinked acryl, in order to adjust a dielectric constant and a coefficient of thermal expansion. The drying and rolling processes may be sequentially or simultaneously performed. The drying process acts to remove the solvent from the prepreg 20, and the rolling process functions to control the thickness of the prepreg 20 to a desired level.

As such, a prepreg 20 obtained by alternately stacking a plurality of resin members 22 having carbon fibers 24 incorporated therein with metal layers 50 may be provided. As a multilayered structure including the metal layers 50 and the resin members 22 having the carbon fibers 24 incorporated therein is formed, heat conductive properties and mechanical properties such as strength of the metal clad laminate 10 may be controlled depending on the end use.

Next, as shown in FIG. 8, the solution of carbon nanoparticles is applied on the bonding surface of the metal foil 40 to the prepreg 20, thus forming the layer 30 of carbon nanoparticles. The solution of carbon nanoparticles may be prepared by dispersing carbon particles having a particle size of ones or nm or μm, such as CNTs, Graphene, carbon black, etc., in a volatile solvent. The volatile solvent may be acetone, or methanol.

As shown in FIG. 9, the metal foil 40 on which the solution of carbon nanoparticles is applied is dried. While the volatile solvent is volatilized by drying the metal foil 40 using hot air, the layer 30 of carbon nanoparticles is formed on the metal foil 40. When the layer 30 of carbon nanoparticles is formed on the bonding surface of the metal foil 40 in this way, the force of adhesion to the prepreg 20 may increase.

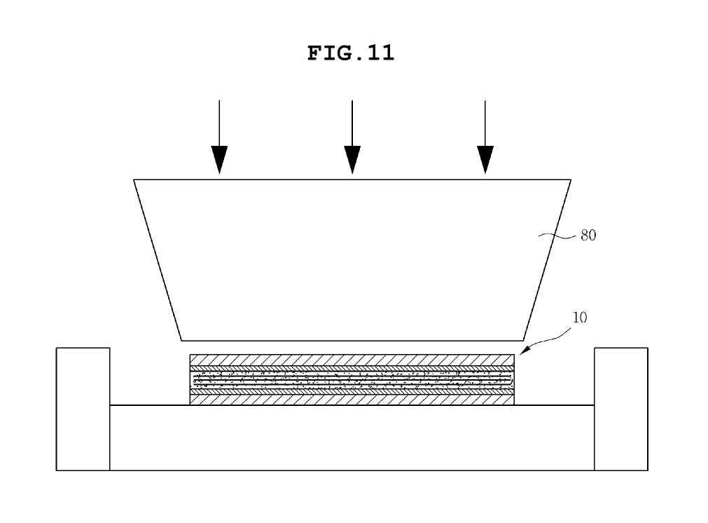

The metal foil 40 on which the layer 30 of carbon nanoparticles is formed is bonded so that the layer 30 of carbon nanoparticles faces one or both surfaces of the prepreg 20. As such, the metal foil 40 may be bonded to the prepreg 20 using pressing at high temperature and high pressure by means of a press. As shown in FIG. 10, the metal foil 40 is formed on both surfaces of the layer 30 of carbon nanoparticles 30, and then, as shown in FIG. 11, the layers are pressed using a press 80. The pressing process may be carried out at a temperature of 150˜180 and a pressure of 9˜20 MPa, but the temperature and pressure conditions are not particularly limited and may be appropriately adjusted depending on the properties of the prepreg 20, the performance of the press 80, or the thickness of the metal clad laminate 10.

As described hereinbefore, the present invention provides a metal clad laminate, a method of manufacturing the same, and a heat-radiating substrate. According to the present invention, the metal clad laminate is configured such that a layer of carbon nanoparticles is formed between bonding surfaces of upper and lower metal foils to a prepreg thus increasing adhesion, and the prepreg has carbon fibers incorporated therein, thus improving heat conductive properties and mechanical properties.

Also, a prepreg having a plurality of metal layers inserted therein can be manufactured by alternately stacking resin members having carbon fibers incorporated therein with the metal layers. The metal layers are inserted in the prepreg, thus improving heat conductive properties, and the number of stacked layers can vary depending on the end use, thus controlling the heat conductive properties and mechanical properties of the metal clad laminate.

Also, a lower metal foil formed under the prepreg can be formed to be thicker than an upper metal foil. When the lower metal foil exposed to the outside is formed thicker, heat transfer effects to the outside can increase.

According to the present invention, the method of manufacturing the metal clad laminate is advantageous because a solution of carbon nanoparticles is applied on the bonding surface of the metal foil to the prepreg thus enhancing the force of adhesion between the metal foil and the prepreg.

Although the embodiments of the present invention regarding the metal clad laminate, the method of manufacturing the same, and the heat-radiating substrate have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A metal clad laminate, comprising:
a prepreg including a resin member and carbon fibers unidirectionally arranged and incorporated therein;
an upper layer of carbon nanoparticles formed on an upper surface of the prepreg; and
an upper metal foil formed on an upper surface of the upper layer of carbon nanoparticles.

2. The metal clad laminate as set forth in claim 1, further comprising:
a lower layer of carbon nanoparticles formed on a lower surface of the prepreg; and
a lower metal foil formed on a lower surface of the lower layer of carbon nanoparticles.

3. The metal clad laminate as set forth in claim 1, wherein the prepreg includes a plurality of metal layers inserted therein.

4. The metal clad laminate as set forth in claim 2, wherein the lower metal foil is thicker than the upper metal foil.

5. The metal clad laminate as set forth in claim 2, wherein the upper metal foil, the lower metal foil and the metal layer are made of an identical metal.

6. The metal clad laminate as set forth in claim 1, wherein the resin member comprises a heat curable resin.

7. The metal clad laminate as set forth in claim 1, wherein the carbon nanoparticles are any one selected from among carbon nanotubes (CNTs), Graphene, and carbon black.

8. A heat-radiating substrate, comprising:
a metal clad laminate comprising a prepreg including a resin member and carbon fibers unidirectionally arranged and incorporated therein, an upper layer of carbon nanoparticles on an upper surface of the prepreg, a lower layer of carbon nanoparticles formed on a lower surface of the prepreg, a circuit layer on an upper surface of the upper layer of carbon nanoparticles, and a lower metal foil formed on a lower surface of the lower layer of carbon nanoparticles; and
an electronic device electrically connected to the circuit layer.

9. The heat-radiating substrate as set forth in claim 8, wherein the prepreg includes a plurality of metal layers inserted therein.

10. The heat-radiating substrate as set forth in claim 8, wherein the lower metal foil is thicker than the circuit layer.

11. A method of manufacturing a metal clad laminate, comprising:
(A) forming a prepreg including a resin member having carbon fibers incorporated therein;
(B) applying a solution of carbon nanoparticles on a bonding surface of a metal foil to the prepreg, thus forming a layer of carbon nanoparticles;
(C) drying the metal foil; and
(D) bonding the metal foil so that the layer of carbon nanoparticles faces one or both surfaces of the prepreg.

12. The method as set forth in claim 11, wherein the forming the prepreg in (A) is carried out by alternately stacking a plurality of resin members having carbon fibers incorporated therein with a plurality of metal layers thus forming a prepreg.

13. The method as set forth in claim 11, wherein the forming the prepreg in (A) is carried out by applying a resin solution on the carbon fibers and then performing drying and rolling thus forming the resin member having the carbon fibers incorporated therein.

14. The method as set forth in claim 11, wherein in (B) the solution of carbon nanoparticles is prepared by mixing carbon nanoparticles with a volatile solvent.

15. The method as set forth in claim 11, wherein the bonding the metal foil in (D) is carried out using a press.
